(19) United States
(12) Patent Application Publication
(10) Pub. No.: US 2008/0157376 A1
(43) Pub. Date: Jul. 3, 2008

(54) Semiconductor Device and Method for Manufacturing the Same

(76) Inventor: JONG BOK LEE, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,882

(22) Filed: Oct. 30, 2007

(30) Foreign Application Priority Data
Dec. 28, 2006 (KR) 10-2006-0135793

(51) Int. Cl. H01L 23/52; H01L 21/4763

(52) U.S. Cl. 257/751; 438/627; 257/E23.141; 257/E21.495

(57) ABSTRACT

A semiconductor device and method for manufacturing the same are disclosed. A semiconductor device according to an embodiment comprises an interlayer insulating layer including a lower conductor wiring layer and a via hole exposing the lower conductor wiring layer, a conductor material filled inside the via hole, and an upper conductor wiring layer electrically connected to the lower conductor wiring layer through the conductor material filled inside the via hole. A barrier layer for inhibiting a loss of the conductor material filled inside the via hole is formed with a portion filling the upper portion of the via hole, and the upper conductor wiring layer is formed on the barrier layer.

### CROSS-REFERENCE TO RELATED APPLICATION

The present application claims the benefit under 35 U.S.C. §119 of Korean Patent Application No. 10-2006-0135793, filed Dec. 28, 2006, which is hereby incorporated by reference in its entirety.

### BACKGROUND

Often, a horizontal wiring of a semiconductor device is formed of copper, copper alloy, aluminum or aluminum alloy. And the vertical (contact) wiring of the semiconductor device can be formed of various metals, but are mainly formed of tungsten (W).

FIGS. 1 to 5 are process views showing a method for manufacturing a semiconductor device of the related art. Referring to FIG. 1, after a via hole 12 is formed in an interlayer insulating layer 10 on a lower metal wiring layer 11, a titanium (Ti) layer 21 and a titanium nitride (TiN) layer 22 are sequentially stacked in the inner wall of the via hole 12.

Then, tungsten (W) filling the inside of the via hole 12 is formed. Thereafter, referring to FIG. 2, a chemical mechanical polishing (CMP) process is performed so that the via hole 12 is polished so that the titanium film 21, the titanium nitride film 22, and the tungsten W are left only in the via hole 12. Thereafter, referring to FIG. 3, a titanium film 23 is formed on the polished resultant product. At this time, the titanium film 23 is formed at a thickness of approximately 100 Å.

Thereafter, referring to FIG. 4, after a horizontal wiring layer 30 formed of copper or copper alloy containing about 95% copper and about 5% aluminum is formed on the titanium film 23, a titanium film 41 and a titanium nitride film 42 are sequentially stacked on the horizontal wiring layer 30, as a diffusion stop layer 40.

Next, a photoresist pattern P is formed on the diffusion stop layer 40. Herein, the photoresist pattern P is for forming a horizontal wiring layer pattern, wherein the photoresist pattern P is formed to be used as an etching mask in a process for removing an unnecessary horizontal wiring layer portion.

Referring to FIG. 5, a horizontal wiring layer pattern 31 is formed by performing the etching process using the photoresist pattern P as an etching mask. At this time, it is the most preferable that the horizontal wiring layer pattern 31 completely covers vertical wirings formed of tungsten positioned in the lower thereof. However, misalignment often occurs. This is the reason that as critical dimension (CD) of the semiconductor device becomes smaller, it is difficult to form the horizontal wiring pattern 31 to precisely cover the vertical wiring.

Referring to FIGS. 5, 6, and 7, as the tungsten (W) filled within the via hole 12 is exposed to the atmosphere in a semiconductor device manufacturing process due to such a misalignment, tungsten loss A occurs due to the diffusion of the tungsten.

### BRIEF SUMMARY

Embodiments of the present invention provide a semiconductor device and a method for manufacturing the same.

A semiconductor device and a method for manufacturing the same according to an embodiment of the present invention is provided capable of inhibiting a loss of a vertical wiring layer, even though misalignment between a horizontal wiring layer and the vertical wiring layer occurs.

An embodiment of the present invention provides a semiconductor device and a method for manufacturing the same capable of inhibiting tungsten loss due to the diffusion of the tungsten used as a vertical wiring layer, even though misalignment between a horizontal wiring layer and the vertical wiring layer occurs.

A method for manufacturing a semiconductor device comprising an interlayer insulating layer including a lower conductor wiring layer and a via hole exposing the lower conductor wiring layer, a conductor material filled inside the via hole, and an upper conductor wiring layer electrically connected to the lower conductor wiring layer through the conductor material filled inside the via hole is provided. In one embodiment, the method comprises forming a barrier layer for inhibiting a loss of the conductor material filled inside the via hole and forming the upper conductor wiring layer on the barrier layer.

A method for manufacturing a semiconductor device according to one embodiment comprises: forming a via hole in an interlayer insulating layer on lower metal wiring layer; sequentially stacking a first titanium film, a first titanium nitride film, and a tungsten layer on the interlayer insulating layer including in the via hole; performing a chemical mechanical polishing process so that the first titanium film, the first titanium nitride film, and the tungsten are left only within the via hole; etching an upper portion of the tungsten; forming a second titanium nitride on the tungsten of which a portion is etched and on the interlayer insulating layer; sequentially forming a second titanium film, a horizontal wiring layer, a third titanium film, and a third titanium nitride film on the second titanium nitride film; and forming a horizontal wiring layer pattern by performing an etching process using a photoresist pattern as an etching mask.

A semiconductor device according to an embodiment comprises: a tungsten contact in a via hole provided in an interlayer insulating layer, the tungsten contact having a height below a top surface of the via hole; a barrier layer on the tungsten contact and a portion of the interlayer insulating layer, the barrier layer filling the via hole; and a horizontal wiring layer pattern on the barrier layer.

The details of one or more embodiments are set forth in the accompanying drawings and the description below. Other features will be apparent from the description and drawings, and from the claims.

### BRIEF DESCRIPTION OF THE DRAWINGS

FIGS. 1 to 5 are process views showing a method for manufacturing a semiconductor device of the related art.

FIG. 6 is a plan view photograph showing tungsten loss occurred in a vertical wiring of a semiconductor device of the related art.

FIG. 7 is a cross-sectional view photograph showing tungsten loss occurred in a vertical wiring of a semiconductor device of the related art.

FIGS. 8 to 13 are process views showing a method for manufacturing a semiconductor device according to an embodiment of the present invention.

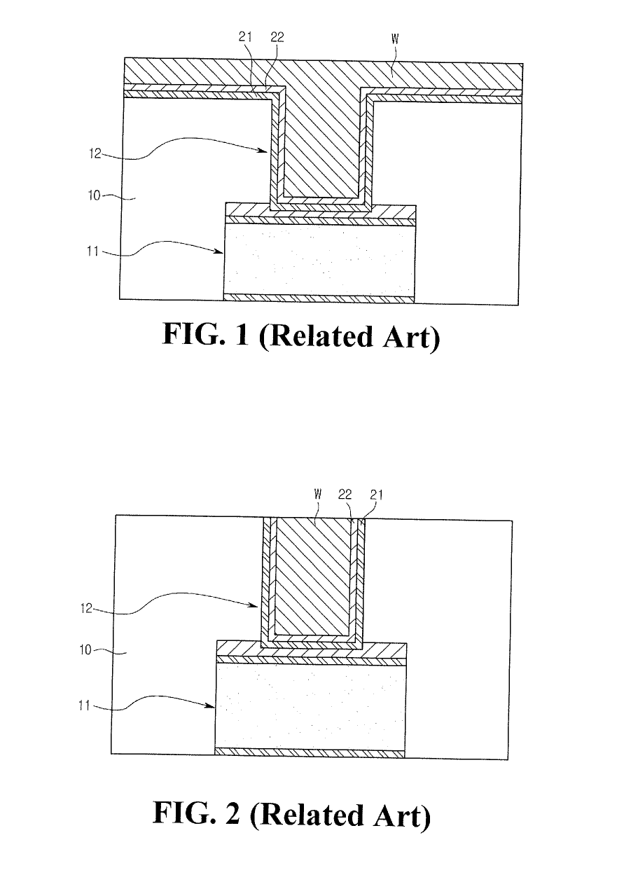

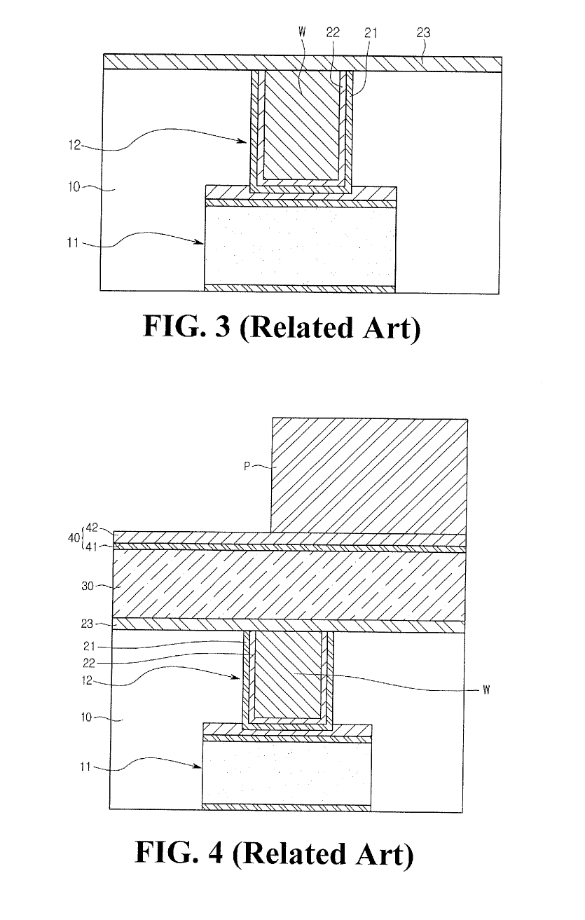

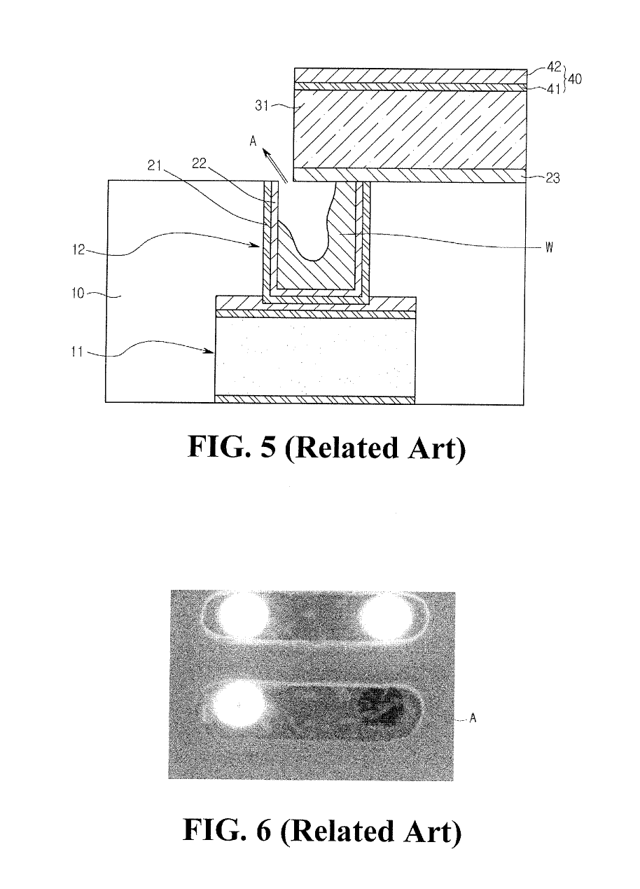

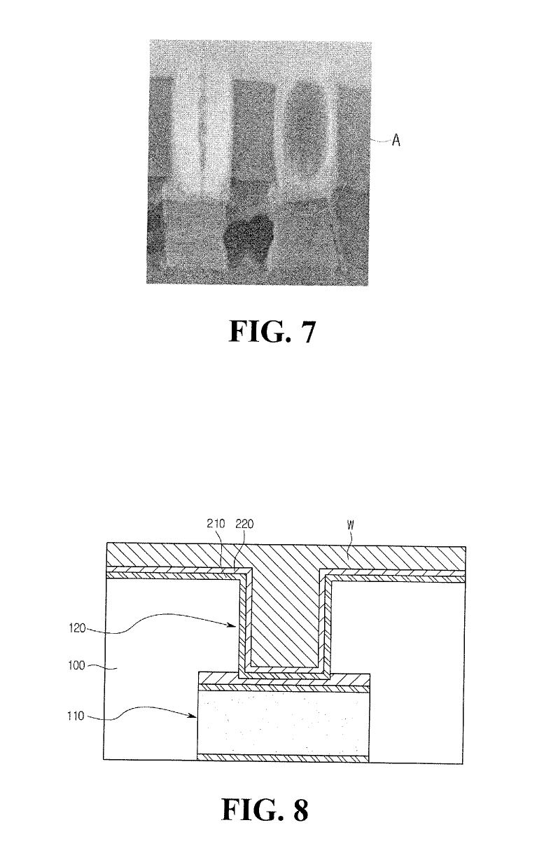

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present. Therefore, the meanings should be judged according to the technical idea of the embodiment.

FIGS. 8 to 13 are process views showing a method for manufacturing a semiconductor device according to an embodiment. Referring to FIG. 8, after a via hole 120 is formed in an interlayer insulating layer 100 above a lower metal wiring layer 110, a first barrier layer can be formed on the interlayer insulating layer 100 and in the via hole 120. The first barrier layer can include, for example, a first titanium film 210 and a first titanium nitride film 220 sequentially stacked in the via hole 120.

In one embodiment, the thickness of the first titanium film 210 may be selected from the range of about 150 Å to about 250 Å, for example at a thickness of 200 Å. Also, the thickness of the first titanium nitride film 220 may be selected from the range of about 80 Å to about 120 Å, for example at a thickness of 100 Å. Following the formation of the first barrier layer, a conductor material filling the inside of the via hole 120 can be formed on the interlayer insulating layer 100. In a preferred embodiment, the conductor material is tungsten W.

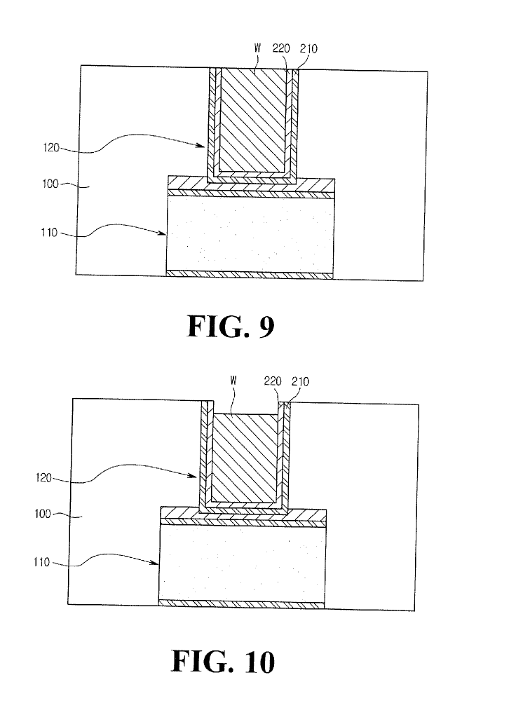

Thereafter, referring to FIG. 9, a chemical mechanical polishing (CMP) process can be performed so that the barrier layer and the conductor material remain only in the via hole. For example, the titanium film 210, the titanium nitride film 220, and the tungsten W are removed from the top surface of the interlayer insulating layer 100 and left only in the via hole 120. Referring to FIG. 10, an upper portion of the conductor material W is etched by performing an etchback process. In one embodiment, the conductor material can be etched back by the thickness selected from the range of about 150 Å to about 250 Å.

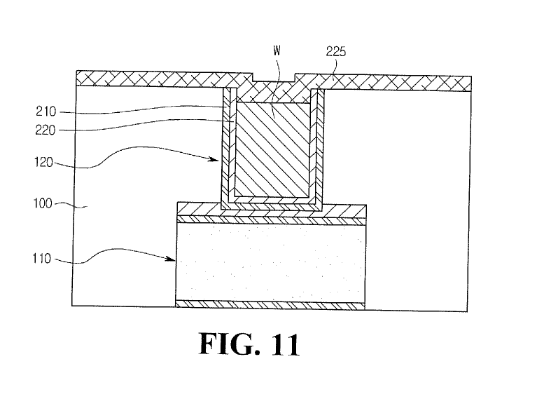

Thereafter, referring to FIG. 11, a second barrier layer can be formed on the interlayer insulating layer 100, filling the upper portion of the via hole. The second barrier layer can be, for example, a second titanium nitride film 225. The second titanium nitride film, or other suitable material, can function as a barrier layer for inhibiting loss of the conductor material, e.g. the tungsten W, filled inside the via hole 120. In one embodiment, the thickness of the second titanium nitride film 225 may be selected from the range of about 250 Å to about 350 Å, for example at a thickness of 300 Å.

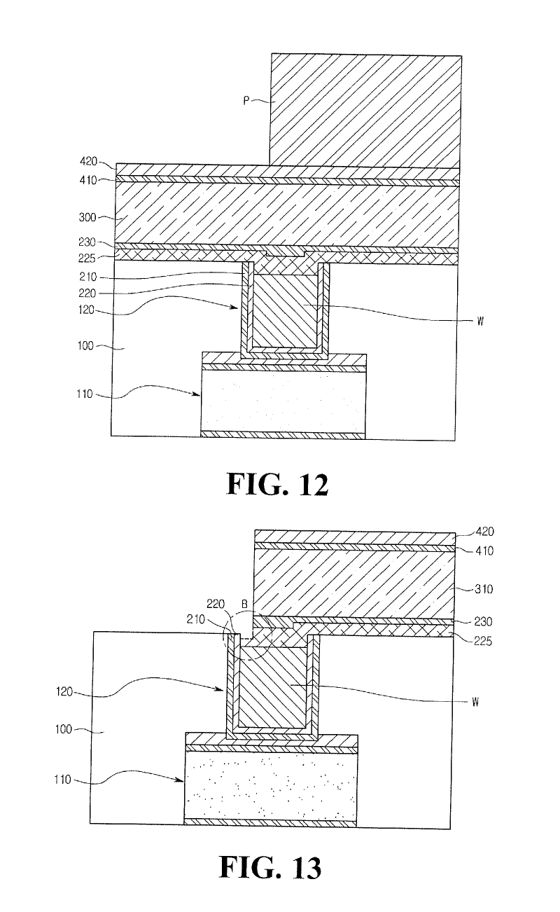

Referring to FIG. 12, material for a horizontal wiring layer can be formed on the resultant structure. In one embodiment, a second titanium film 230, a horizontal wiring layer 300, a third titanium film 410, and a third titanium nitride film 420 can be sequentially formed on the second titanium nitride film 225. According to an embodiment, the thickness of the second titanium film 230 may be selected from the range of about 80 Å to about 120 Å, for example at a thickness of 100 Å.

The horizontal wiring layer 300 can be formed of, for example, copper or copper alloy containing about 95% copper and about 5% aluminum. The thickness of the horizontal wiring layer 300 may be selected from the range of about 4000 Å to about 5000 Å, for example at a thickness of 4500 Å.

Herein, the second titanium nitride film 225, the second titanium film 230, the third titanium film 410, and the third titanium nitride film 420 serve as diffusion stop layers. Also, the thickness of the third titanium film 410 may be selected from the range of about 30 Å to about 70 Å, for example at a thickness of 50 Å. In addition, the thickness of the third titanium nitride film 420 may be selected from the range of about 400 Å to about 800 Å, for example at a thickness of 600 Å.

Continuously, a photoresist pattern P can be formed on the third titanium nitride film 420. Herein, the photoresist pattern P is for forming a horizontal wiring layer pattern, wherein the photoresist pattern P is formed to be used as an etching mask in a process for removing an unnecessary horizontal wiring layer portion. The size of the device can be smaller as the integration of the semiconductor device is increased. The reafter, referring to FIG. 13, the horizontal wiring layer pattern 310 can be formed by performing an etching process using the photoresist pattern P as an etching mask.

At this time, it is preferable that the horizontal wiring layer pattern 310 completely covers vertical wirings formed of tungsten positioned in the lower thereof. However, misalignment often occurs.

However, differently from the related art, the conductor material such as tungsten filled in the inside of the via hole 120 is covered with the barrier layer such as the second titanium nitride film 225, making it possible to inhibit the tungsten loss due to the diffusion of the tungsten, even though the misalignment between the horizontal wiring layer and the vertical wiring occurs. This is shown as a B part of FIG. 13. The second titanium nitride film 225 formed as the barrier layer remains even after the upper conductor wiring layer is formed, to cover the upper end of the tungsten W, i.e. the conductor material filled inside the via hole 120.

Referring to FIG. 13, in the semiconductor device according to embodiments of the present invention, a via hole 120 is provided in an interlayer insulating layer 100 above a lower metal wiring layer 110, and a barrier layer including, for example, a stacked first titanium film 210 and first titanium nitride film 220 on the inner walls of the via hole 120. In one embodiment, the thickness of the first titanium film 210 can be between about 150 Å and about 250 Å, and the thickness of the first titanium nitride film 220 can be between about 80 Å and about 120 Å.

The inside of the via hole 120 having the first barrier layer is filled with a conductor material and a second barrier layer on the conductor material. In an embodiment, the inside of the via hole 120 is filled with tungsten W and a second titanium nitride film 225 on the tungsten W. The second titanium nitride film 225 can be provided along a top surface of the interlayer insulating layer 100 in addition to being in the upper portion of the via hole 120. In one embodiment, the thickness of the second titanium nitride film 225 can be between about 250 Å and 350 Å.

A horizontal wiring can be connected to the lower wiring layer 110 through the vertical wiring of the conductor material. In one embodiment, a second titanium film 230, a horizontal wiring layer pattern 310, a third titanium film 410, and a third titanium nitride film 420 on the second titanium nitride film 225 can form the horizontal wiring. In one embodiment, the thickness of the second titanium film 230 can be between about 80 Å and about 120 Å, the thickness of the third titanium film 410 can be between about 30 Å and about 70 Å, and the thickness of the third titanium nitride film 420 can be between about 400 Å and about 800 Å.

Although the barrier metals 210, 220, 225, 230, 410, and 420 are described as titanium and titanium nitride, embodiments of the present invention are not limited thereto. Other suitable barrier metals can be used, and the number of film layers can be modified as needed.

With the semiconductor device and the method for manufacturing the same according to embodiments of the present invention, the tungsten loss due to the diffusion of the tungsten can be inhibited even though misalignment may occur between the horizontal wiring layer and the vertical wiring. Accordingly, the increase of the unnecessary manufacturing costs can be reduced and the electrical characteristics of the semiconductor device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
depositing a metal layer on an interlayer insulating layer in a via hole above a lower metal wiring;
performing a chemical mechanical polishing process such that the metal layer remains only within the via hole;
etching back an upper portion of the metal layer in the via hole;
forming a first barrier layer on the interlayer insulating layer including on the etched back metal layer in the via hole;
forming an upper metal wiring layer on the first barrier layer; and
performing an etching process to form an upper metal wiring.

2. The method according to claim 1, further comprising depositing an initial barrier layer on the interlayer insulating layer in the via hole before depositing the metal layer.

3. The method according to claim 2, wherein the initial barrier layer comprises a first titanium film and a first titanium nitride film.

4. The method according to claim 3, wherein the thickness of the first titanium film is selected from the range of about 150 Å to about 250 Å, and the thickness of the first titanium nitride film is selected from the range of about 80 Å to about 120 Å.

5. The method according to claim 1, wherein etching back an upper portion of the metal layer in the via hole comprises etching the metal layer back by a thickness selected from the range of about 150 Å to about 250 Å.

6. The method according to claim 1, wherein the first barrier layer inhibits loss of the metal layer filled inside the via hole.

7. The method according to claim 1, wherein the first barrier layer comprises a second titanium nitride film.

8. The method according to claim 7, wherein the thickness of the second titanium nitride film is selected from the range of about 250 Å to about 350 Å.

9. The method according to claim 1, wherein forming an upper metal wiring layer comprises:
forming a second titanium film on the first barrier layer;
forming a horizontal wiring layer on the second titanium film;
forming a third titanium film on the horizontal wiring layer; and
forming a third titanium nitride film on the third titanium film.

10. The method according to claim 9, wherein the thickness of the second titanium film is selected from the range of about 80 Å to about 120 Å, the thickness of the horizontal wiring layer is selected from the range of about 4000 Å to about 5000 Å, the thickness of the third titanium film is selected from the range of about 30 Å to about 70 Å, and the thickness of the third titanium nitride film is selected from the range of about 400 Å to about 800 Å.

11. The method according to claim 1, wherein the metal layer comprises tungsten (W).

12. The method according to claim 1, wherein the first barrier layer remains on the via hole such that the upper surface of the metal layer filled inside the via hole is covered after performing the etching process to form the upper metal wiring.

13. A semiconductor device, comprising:
an interlayer insulating layer including a via hole exposing a lower metal wiring layer;
tungsten filled inside the via hole, wherein the top surface of the tungsten is below the top surface of the via hole;
a first barrier layer on the tungsten and a portion of the interlayer insulating layer, wherein the first barrier layer fills a top portion of the via hole; and
an upper metal wiring layer on the first barrier layer.

14. The semiconductor device according to claim 13, further comprising a first titanium film and a first titanium nitride film stacked along the inner walls of the via hole around the tungsten.

15. The semiconductor device according to claim 14, wherein the thickness of the first titanium film is between about 150 Å and about 250 Å, and the thickness of the first titanium nitride film is between about 80 Å and about 120 Å.

16. The semiconductor device according to claim 13, wherein the first barrier layer comprises a second titanium nitride film.

17. The semiconductor device according to claim 16, wherein the thickness of the second titanium nitride film is between about 250 Å and about 350 Å.

18. The semiconductor device according to claim 13, wherein the upper metal wiring layer comprises:
a second titanium film on the first barrier layer;
a horizontal wiring layer pattern on the second titanium film;
a third titanium film on the horizontal wiring layer pattern; and
a third titanium nitride film on the third titanium.

19. The semiconductor device according to claim 18, wherein the horizontal wiring layer pattern comprises copper or a copper alloy.

20. The semiconductor device according to claim 18, wherein the thickness of the second titanium film is between about 80 Å and about 120 Å, the thickness of the horizontal wiring layer is between about 4000 Å and about 5000 Å, the thickness of the third titanium film is between about 30 Å and 70 Å, and the thickness of the third titanium nitride film is between about 400 Å and about 800 Å.
